(19) United States
(12) Patent Application Publication
(10) Pub. No.: US 2026/0129826 A1
(43) Pub. Date: May 7, 2026

(54) SUBSTRATE ISOLATION IN A THREE DIMENSIONAL (3D) MEMORY ARRAY

(71) Applicant: Micron Technology, Inc., Boise, ID (US)

(72) Inventors: Alyssa N. Scarbrough, Boise, ID (US); Frank Speetjens, Boise, ID (US); Jordan D. Greenlee, Boise, ID (US)

(21) Appl. No.: 19/371,000

(22) Filed: Oct. 28, 2025

Related U.S. Application Data
(60) Provisional application No. 63/715,883, filed on Nov. 4, 2024.

(51) Int. Cl. H10B 12/00

(52) U.S. Cl. CPC H10B 12/30; H10B 12/03; H10B 12/05

(57) ABSTRACT

Systems, methods, and apparatus are provided for substrate isolation in a three-dimensional (3D) memory array. The 3D array of vertically stacked memory cells can include a substrate, a horizontal dielectric material formed on the substrate, a 3d array of vertically stacked memory cells formed on the dielectric material, wherein the vertically stacked memory cells have horizontally oriented access devices and horizontally oriented storage nodes, and vertical sense line material formed adjacent to, and in contact with, the horizontally oriented access device.

The vertical sense line material is formed on the horizontal dielectric material such that a bottom portion of the vertical sense line material extends below a bottom surface of the 3D array of vertically stacked memory cells and into the horizontal dielectric material.

### PRIORITY INFORMATION

This application claims the benefit of U.S. Provisional Application No. 63/715,883, filed on Nov. 4, 2024, the contents of which are incorporated herein by reference.

### TECHNICAL FIELD

The present disclosure relates generally to memory devices, and more particularly, to substrate isolation in a 3D memory array.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) memory in accordance with a number of embodiments of the present disclosure.

FIG. 1B is a perspective view illustrating a portion of a horizontal access devices in vertical three dimensional (3D) memory in accordance with a number of embodiments of the present disclosure.

FIG. 2 illustrates a portion of a horizontal access device in vertical three dimensional (3D) memory in accordance with a number of embodiments of the present disclosure.

FIG. 3 is a schematic illustration of a vertical three dimensional memory in accordance with a number of embodiments of the present disclosure.

FIG. 4 is a perspective view illustrating horizontal access devices in accordance with a number of embodiments of the present disclosure.

FIG. 5 is a cross-sectional view of a vertical stack in vertical three dimensional (3D) memory in accordance with a number of embodiments of the present disclosure.

FIGS. 6A to 6I illustrate an example method, at one stage of a semiconductor fabrication process, for substrate isolation in a 3D memory array, in accordance with a number of embodiments of the present disclosure.

FIG. 7 is a block diagram of an apparatus in the form of a computing system including a memory device in accordance with a number of embodiments of the present disclosure.

### DETAILED DESCRIPTION

Embodiments of the present disclosure describe substrate isolation in a three dimensional (3D) memory array. A memory device can include a substrate, a horizontal dielectric material formed on the substrate, a 3D array of vertically stacked memory cells formed on the dielectric material, wherein the vertically stacked memory cells have horizontally oriented access devices and horizontally oriented storage nodes. The memory device can also include a vertical sense line material formed adjacent to, and in contact with, the horizontally oriented access devices, wherein the vertical sense line material is formed on the horizontal dielectric material such that a bottom portion of the vertical sense line material extends below a bottom surface of, the 3D array of vertically stacked memory cells into the horizontal dielectric material.

In some previous approaches, substrate isolation in 3D memory arrays of vertically stacked memory cells does not scale with the number of layers of memory in a memory stack. The more layers of memory that a memory stack includes, the more difficult it is to stop an etch on a bottom-most silicon (Si) layer in a memory stack. Failing to stop an etch on a bottom-most Si layer can result in the performance of the material deposited in the opening formed by the etch not functioning as intended to being formed to unintended dimensions.

Embodiments described herein, however, can an etch more consistently stopping in the intended layer of material. This can be achieved by replacing a bottom layer of a Si material or SiGe material with a dielectric material. By replacing the bottom layer of Si material or SiGe material, an etch can form an opening that goes through every layer of Si and SiGe material, the layer of dielectric material can function as a layer on which the etch can stop so it doesn't reach the substrate, and a memory array can be electrically isolated from the substrate on which it was formed.

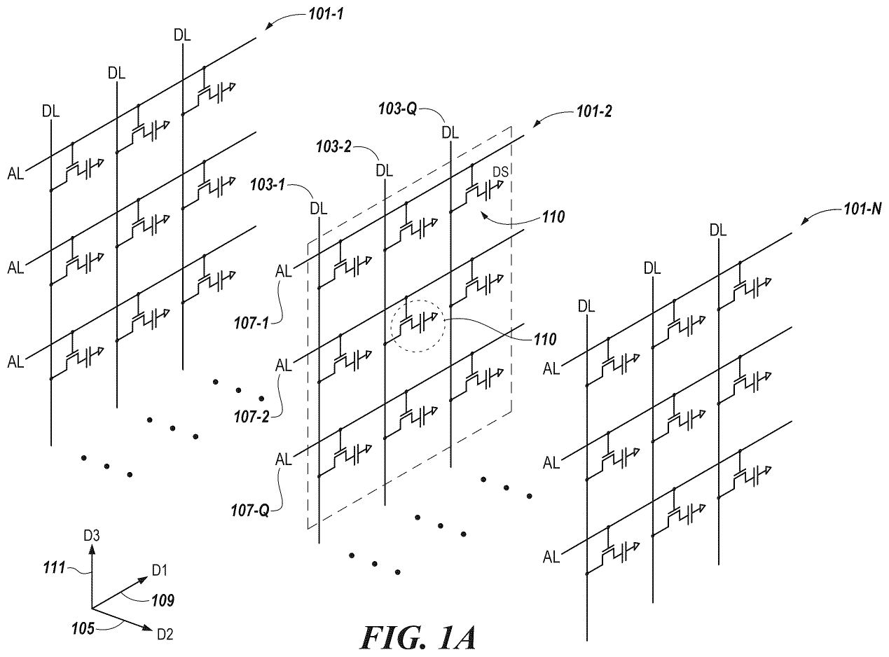

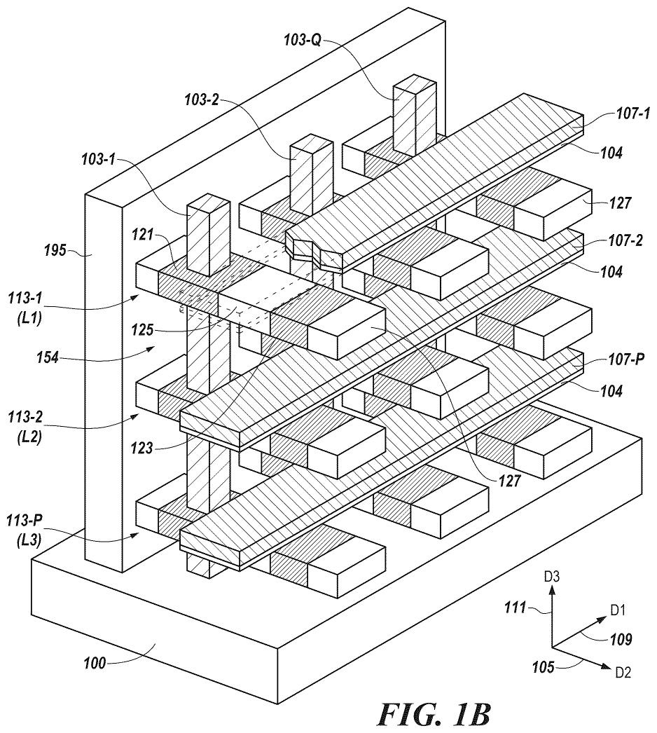

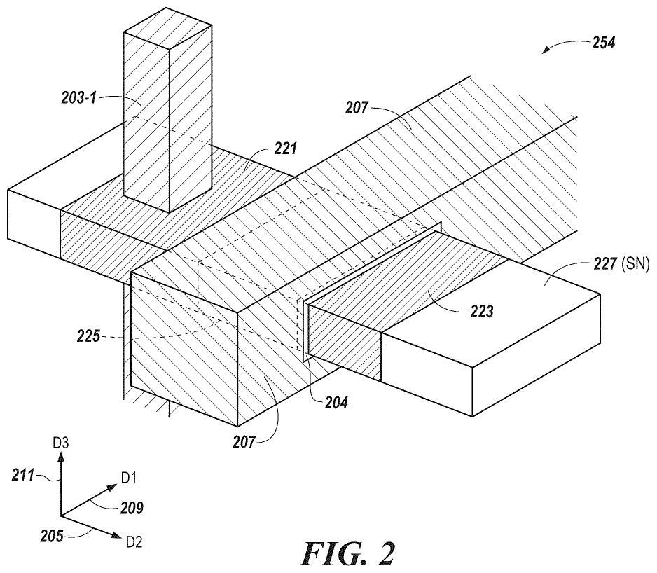

The figures herein follow a numbering convention in which the first digit or digits correspond to the figure number of the drawing and the remaining digits identify an element or component in the drawing. Similar elements or components between different figures may be identified by the use of similar digits. For example, reference numeral 107 may reference element “07” in FIG. 1A, and a similar element may be referenced as 207 in FIG. 2. Multiple analogous elements within one figure may be referenced with a reference numeral followed by a hyphen and another numeral or a letter. For example, 107-1 may reference element 107-1 in FIG. 1A and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1A is a schematic illustration of an array of memory cells in a vertical three dimensional (3D) memory in accordance with a number of embodiments of the present disclosure. FIG. 1A illustrates that a cell array may have a plurality of sub cell arrays 101-1, 101-2, . . . 101-N. The sub cell arrays 101-1, 101-2, . . . 101-N may be arranged along a second direction (D2) 105. Each of the sub cell arrays, e.g., sub cell array 101-2, may include a plurality of access lines 107-1, 107-2, . . . , 107-Q (which also may be referred to as word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-1, 101-2, . . . , 101-N, and the digit lines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one digit line, e.g., 103-2. Each memory cell 110 may be uniquely addressed through a combination of an access line 107-1, 107-2, . . . , 107-Q and a digit line 103-1, 103-2, . . . , 103-Q.

The access lines 107-1, 107-2, . . . , 107-Q may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., a first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B illustrates a perspective view showing a three dimensional (3D) semiconductor memory device, e.g., a portion of a sub cell array 101-2 shown in FIG. 1A as a vertically oriented stack of memory cells in an array, according to some embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon (Si) substrate, a germanium (Ge) substrate, or a silicon-germanium (SiGe) substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111.

The plurality of discrete components to the laterally oriented access devices 154, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . ,107-Q may be analogous to the access lines 107-1, 107-2, . . . , 107-Q shown in FIG. 1A. The plurality of horizontally oriented access lines 107-1, 107-2, . . . , 107-Q may be arranged, e.g., “stacked”, along the third direction (D3) 111. The plurality of horizontally oriented access lines 107-1, 107-2, . . . , 107-Q may include a conductive material. For example, the conductive material may include one or more of a doped semiconductor, e.g., doped Si, doped Ge, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

The horizontally oriented memory cells, e.g., memory cell 110 in FIG. 1A, may be spaced apart from one another horizontally in the first direction (D1) 109. The plurality of discrete components to the horizontally oriented access devices 154, e.g., first source/drain region 121 and second source/drain region 123 separated by a channel region 125, can extend laterally in the second direction (D2) 105, and the plurality of horizontally oriented access lines 107-1, 107-2, . . . , 107-Q can extend laterally in the first direction (D1) 109. For example, the plurality of horizontally oriented access lines 107-1, 107-2, . . . , 107-Q, extending in the first direction (D1) 109, may be formed on a top surface opposing and electrically coupled to the channel regions 125, separated therefrom by a gate dielectric, and orthogonal to horizontally oriented access devices 154, e.g., transistors, extending in laterally in the second direction (D2) 105.

As shown in the example embodiment of FIG. 1B, the digit lines, 103-1, 103-2, . . . , 103-Q, extend in a vertical direction with respect to the substrate 100, e.g., in a third direction (D3) 111. Further, as shown in FIG. 1B, the digit lines, 103-1, 103-2, . . . , 103-Q, in one sub cell array, e.g., sub cell array 101-2 in FIG. 1A, may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 154, e.g., transistors, extending laterally in the second direction (D2) 105. Each of the digit lines, 103-1, 103-2, . . . , 103-Q, may vertically extend, in the third direction (D3), on sidewalls adjacent first source/drain regions 121 of respective ones of the plurality of horizontally oriented access devices 154, e.g., transistors, that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 154, a sidewall of a first source/drain region 121 of a first one of the horizontally oriented access devices 154, and a sidewall of a first source/drain region 121 a first one of the horizontally oriented access devices 154, etc. Similarly, a second one of the vertically extending digit lines, e.g., 103-2, may be adjacent a sidewall to a first source/drain region 121 of a second one of the horizontally oriented access devices 154, spaced apart from the first one of horizontally oriented access devices 154 in the first direction (D1) 109. And the second one of the vertically extending digit lines, e.g., 103-2, may be adjacent a sidewall of a first source/drain region 121 of a second one of the laterally oriented access devices 154, and a sidewall of a first source/drain region 121 of a second one of the horizontally oriented access devices 154, etc.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices 154 above the substrate 100. The body contact 195 may be connected to a body e.g., body region, of the horizontally oriented access devices 154, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 254, e.g., transistors. The first and the second source/drain regions may be separated by a channel 225 formed in a body of semiconductor material, e.g., body region of the horizontally oriented access devices 254, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 254, e.g., transistors, may be formed of a low doped p-type (p-) semiconductor material. In one embodiment, the body region and the channel 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc.

Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 254, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 254, e.g., transistors. The first and the second source/drain regions may be separated by a channel 225 formed in a body of semiconductor material, e.g., body region, of the horizontally oriented access devices 254, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 254, e.g., transistors. For example, the first source/drain region 221 may have a bottom surface within the body of the horizontally oriented access device 254 which is located higher, vertically in the third direction (D3) 211, than a bottom surface of the body of the laterally, horizontally oriented access device 254. As such, the laterally, horizontally oriented access device 254 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-Q shown in FIG. 1, may be disposed on a top surface opposing and coupled to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 204 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . . , 103-Q in FIG. 1, may be vertically extending in the third direction (D3) 211 adjacent a sidewall of the first source/drain region 221 in the body to the horizontally oriented access devices 254, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 254, e.g., transistors. For example, the first source/drain region 221 may have a bottom surface within the body of the horizontally oriented access device 254 which is located higher, vertically in the third direction (D3) 211, than a bottom surface of the body of the laterally, horizontally oriented access device 254. As such, the laterally, horizontally oriented transistor 254 may have a body portion which is below the first source/drain region 221 and is in contact with the body contact. An insulator material may fill the body contact such that the first source/drain region 221 may not be in electrical contact with channel 225. Further, as shown in the example embodiment of FIG. 2, an access line, e.g., 207, analogous to the access lines 107-1, 107-2, . . . , 107-Q shown in FIG. 1, may disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent, and in electrical contact with, the first source/drain regions 221. The digit line may be formed asymmetrically to reserve room for a body contact in the channel region 225.

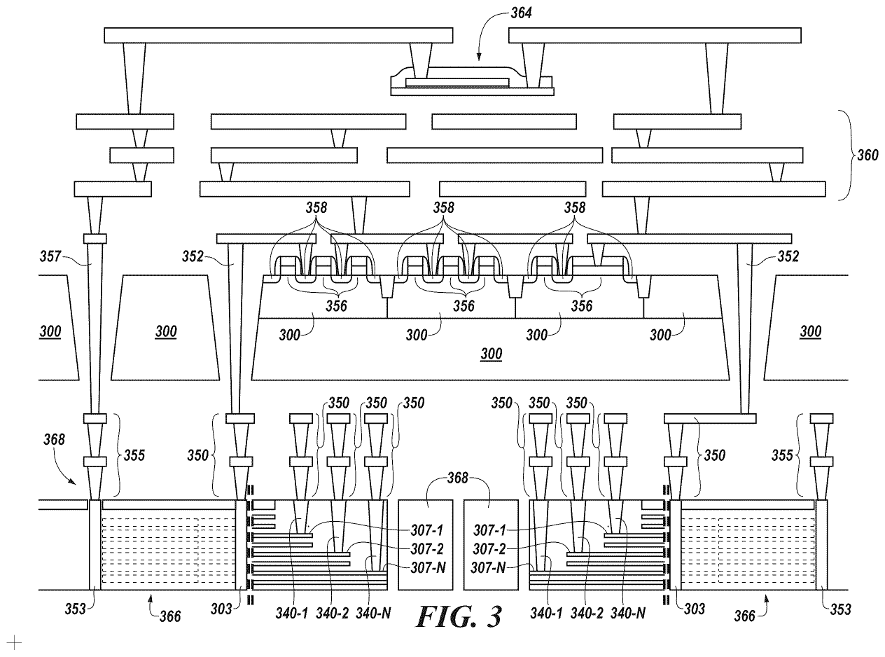

FIG. 3 is a schematic illustration of a vertical three dimensional (3D) memory in accordance with a number of embodiments of the present disclosure. FIG. 3 includes horizontally oriented access lines 307-1, 307-2, . . . , 307-N (individually or collectively referred to as horizontally access lines 307), access line contacts 340-1, 340-2, . . . , 340-N (individually or collectively referred to as access line contacts 340), and vertically oriented sense lines 303.

FIG. 3 illustrates different portions of the vertical 3D memory at different vertical heights of the vertical 3D memory. In the portion of the vertical 3D memory at the lowest vertical height shown in FIG. 3, FIG. 3 illustrates a staircase structure in a periphery of the vertical 3D memory that includes horizontally oriented access lines 307. As used herein, the term “periphery of the vertical 3D memory” refers to an area at an edge of the vertical 3D memory. For example, in FIG. 3, the periphery of the vertical 3D memory can refer to the portion of the vertical 3D memory that includes an area of a structure within the vertical 3D memory that is adjacent a vertical opening that separates a portion of the vertical 3D from a different portion of the vertical 3D memory. For example, the horizontally oriented access lines 307 are in a portion of the vertical 3D memory (e.g., the periphery) that is adjacent a vertical opening that separates this portion of the vertical 3D memory from vertical pillars 368.

FIG. 3 further illustrates access line contacts 340 coupled to the access lines 307. In some embodiments, the access line contacts 340 can be coupled to conductive lines 350. In some embodiments, conductive lines 350 can be coupled to a power source that can supply power to the access lines 307 through the access line contacts 340. Portions 366 of the vertical 3D memory can include dielectric materials and conductive materials and layers of silicon material.

At a portion of the vertical 3D memory array that is located at a higher vertical height than the previously described portion of the vertical 3D memory, FIG. 3 illustrates a plurality of transistors 356 formed on substrate materials 300. The substrate material 300 can be doped to form source/drain regions 358. Conductive lines 352 can be coupled to conductive lines 350 at a lower vertical height than conductive lines 352 and coupled to conductive lines 360 that are at a higher vertical height than conductive lines 352. Further, conductive lines 360 can be coupled to memory component 364.

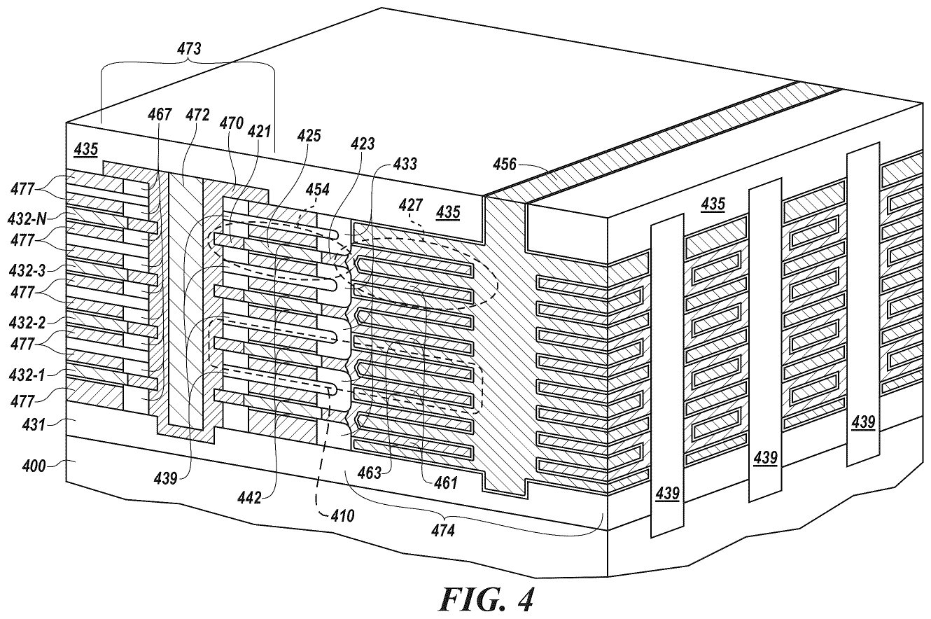

FIG. 4 is a perspective view of a three-dimensional (3D) dynamic random access memory (DRAM) array having horizontally oriented memory cells 410. The example embodiment of FIG. 4 is illustrating an array of 3D DRAM having horizontally oriented memory cells 410 combinable with multi-wafer logic in accordance with a number of embodiments of the present disclosure. The horizontally oriented memory cells 410 in the array comprise horizontally oriented access devices 454 having first source/drain regions 421 and second source/drain regions 423 separated by channel regions 425. Horizontally oriented access lines 477 form gates separated from the channel regions 425 by gate dielectric material 442. As shown in the example embodiment, horizontally oriented storage nodes 427 in a storage node region 474 are electrically coupled to the second source/drain regions 423 of the horizontally oriented access devices 454. The horizontally oriented storage nodes 427 include a first electrode 461, e.g., bottom electrode, and a second electrode 456, e.g., top electrode and/or common node, separated by a dielectric material. In some embodiments, the horizontally oriented storage nodes 427 are multi-sided storage nodes, e.g., double sided-capacitors, as shown in FIG. 4. Vertically oriented digit lines 473 are electrically connected to the first source/drain regions 421 of the horizontally oriented access devices 454. In some embodiments, a portion 470 of the vertically oriented digit lines 473 is epitaxially formed (e.g., grown). The digit line 473 can comprise conductive material 470 and metal material 472.

FIG. 4 can further include a substrate 400 on which the memory array was formed. Further, FIG. 4 can include a dielectric material 431 formed between the array of memory cells and the substrate 400. FIG. 4 also includes a mask material 435.

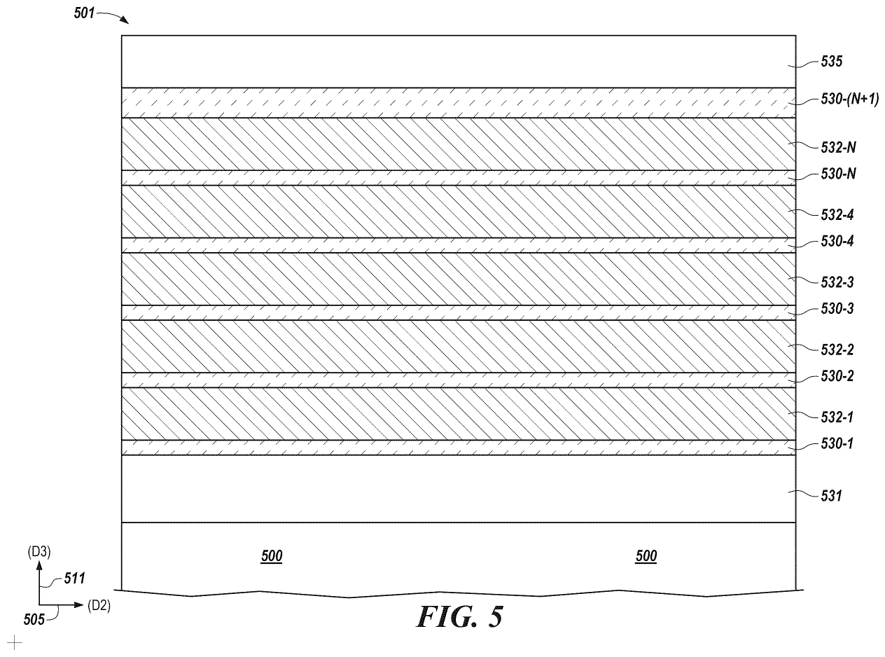

FIG. 5 is a cross-sectional view of a vertical stack in vertical three dimensional (3D) memory in accordance with a number of embodiments of the present disclosure. In the example embodiment shown in the example of FIG. 5, a method of forming the vertical stack 501 can comprise forming alternating layers of a silicon germanium (SiGe) material, 530-1, 530-2, . . . , 530-N (collectively referred to as silicon germanium (SiGe) 530), and a silicon (Si) material, 532-1, 532-2, . . . , 532-N (collectively referred to as silicon (Si) material 532), in repeating iterations to form a vertical stack 501 on a working surface of a semiconductor substrate 500. In some embodiments, the silicon germanium (SiGe) material 530 and the silicon (Si) material 532 can be epitaxially grown. In some embodiments, the Si material 530 can be single crystalline Si material.

In one embodiment, the silicon germanium (SiGe) 530 can be deposited to have a thickness, e.g., vertical height in the third direction (D3), in a range of five (5) nanometers to thirty (30) nm. In one embodiment, the silicon (Si) material 532 can be deposited to have a thickness, e.g., vertical height, in a range of thirty (30) nanometers (nm) to sixty (60) nm. Embodiments, however, are not limited to these examples. As shown in FIG. 5, a vertical direction 511 is illustrated as a third direction (D3), e.g., z-direction in an x-y-z coordinate system, analogous to the third direction (D3), among first, second, and third directions, shown in FIGS. 1-3.

In some embodiments, the silicon germanium (SiGe), 530-1, 530-2, . . . , 530-N, may be a mix of silicon (Si) and germanium (Ge). By way of example, and not by way of limitation, the silicon germanium (SiGe) material 530 may be grown on the substrate material 500. Embodiments are not limited to these examples. In some embodiments, the single crystalline silicon (Si) material, 532-1, 532-2, . . . , 532-N, may comprise a silicon (Si) material in a polycrystalline and/or amorphous state. The single crystalline silicon (Si) material, 532-1, 532-2, . . . , 532-N, may be a low doped, p-type (p-) single crystalline silicon (Si) material. The silicon (Si) material, 532-1, 532-2, . . . , 532-N, may also be formed on the silicon germanium (SiGe) 530. If the silicon germanium (SiGe) 530 was epitaxially grown, the seed is turned to pure silicon after the silicon germanium (SiGe) 530 has been formed.

The repeating iterations of alternating silicon germanium (SiGe), 530-1, 530-2, . . . , 530-N layers and single crystalline silicon (Si) material, 532-1, 532-2, . . . , 532-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to form the vertical stack 501.

The layers may occur in repeating iterations vertically. For example, the vertical stack 501 may include: a first silicon germanium (SiGe) material 530-1, a first single crystalline silicon (Si) material 532-1, a second silicon germanium (SiGe) material 530-2, a second single crystalline silicon (Si) material 532-2, a third silicon germanium (SiGe) material 530-3, and a third single crystalline silicon (Si) material 532-3, in further repeating iterations. Embodiments, however, are not limited to this example and more or fewer repeating iterations may be included. In some examples, photolithographic mask 535 may be deposited over a silicon germanium (SiGe) material 530.

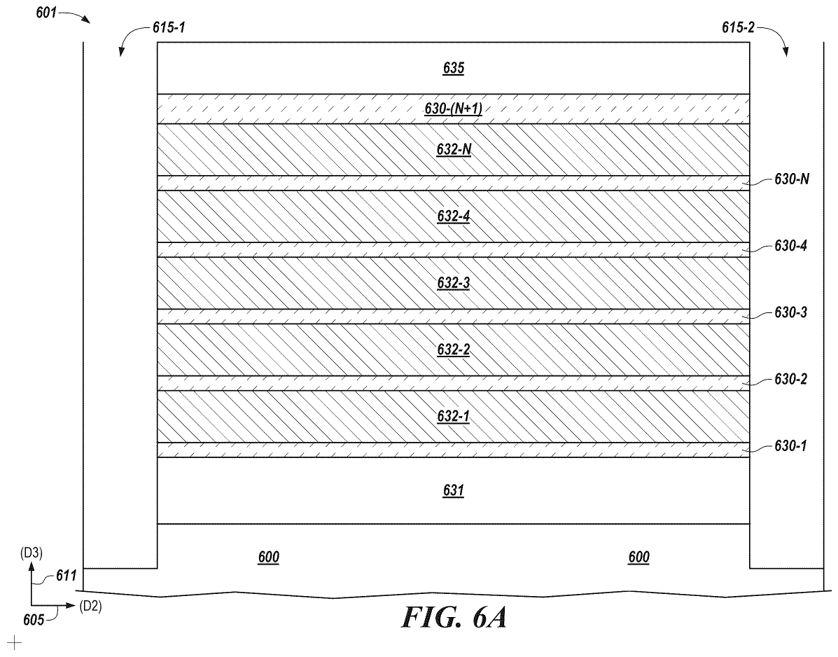

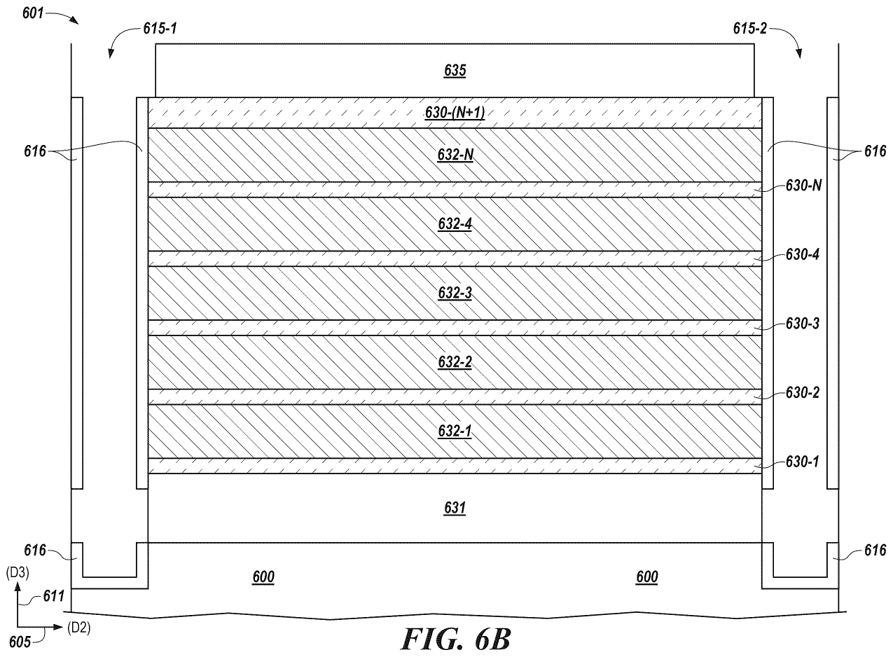

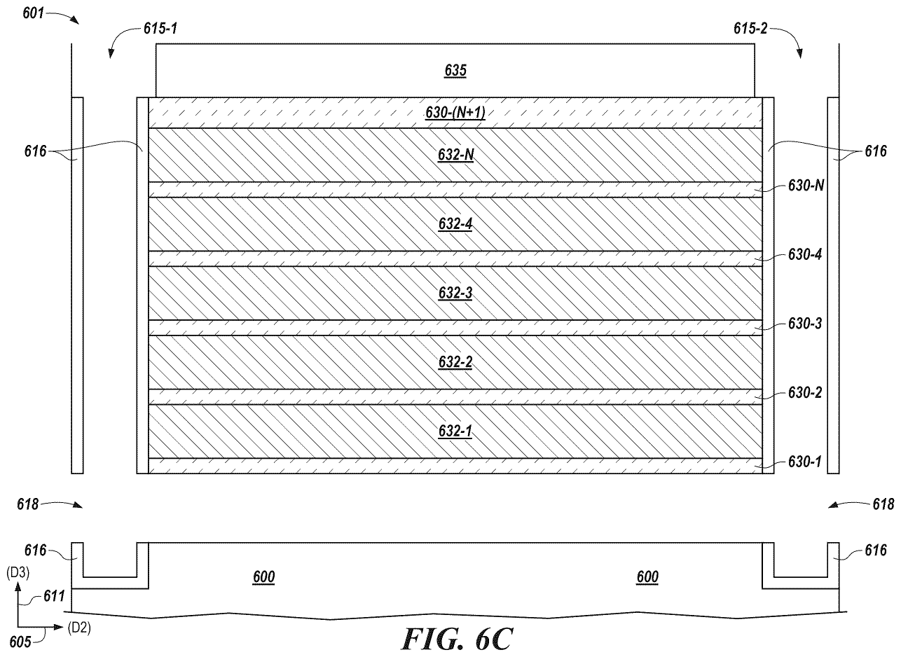

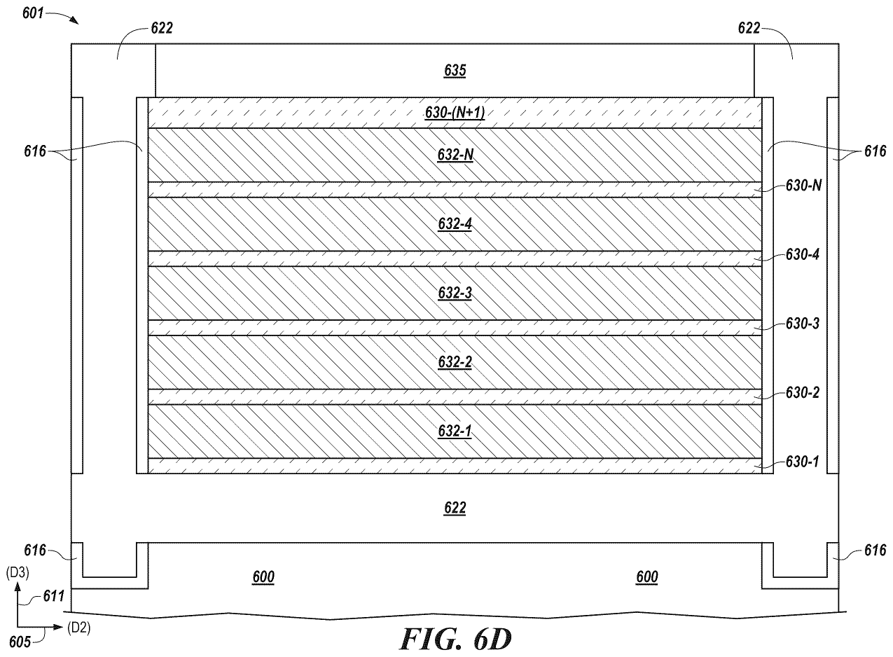

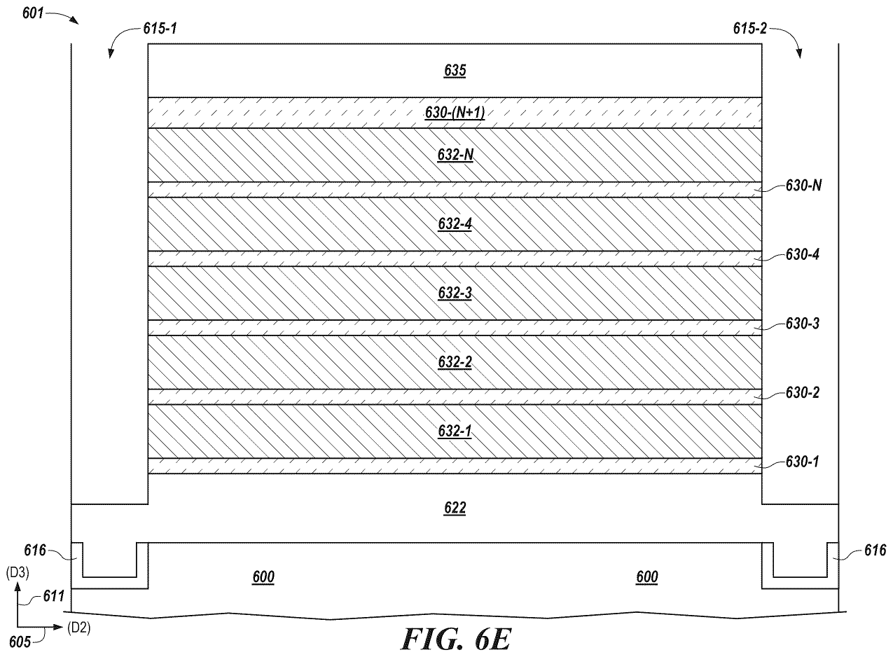

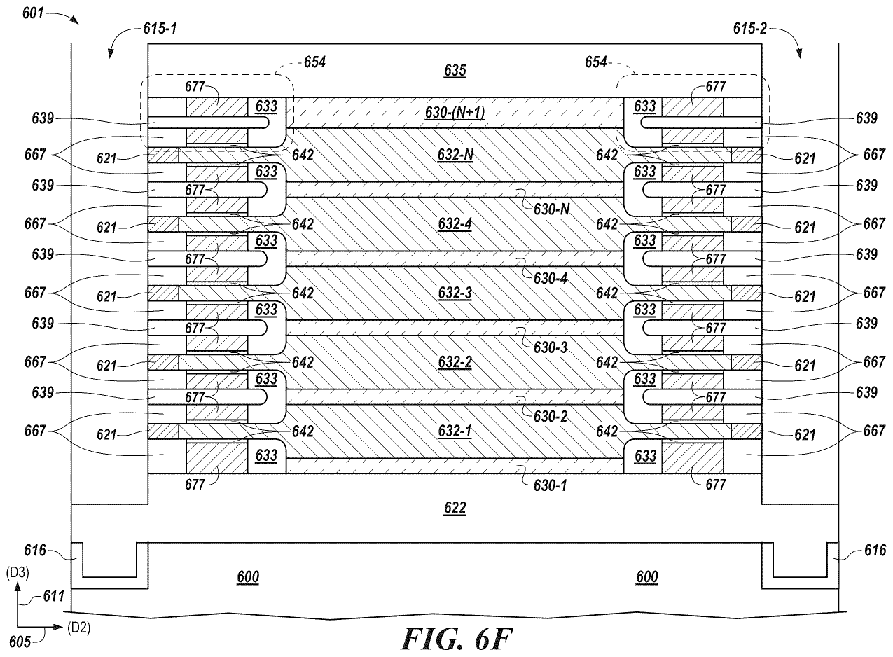

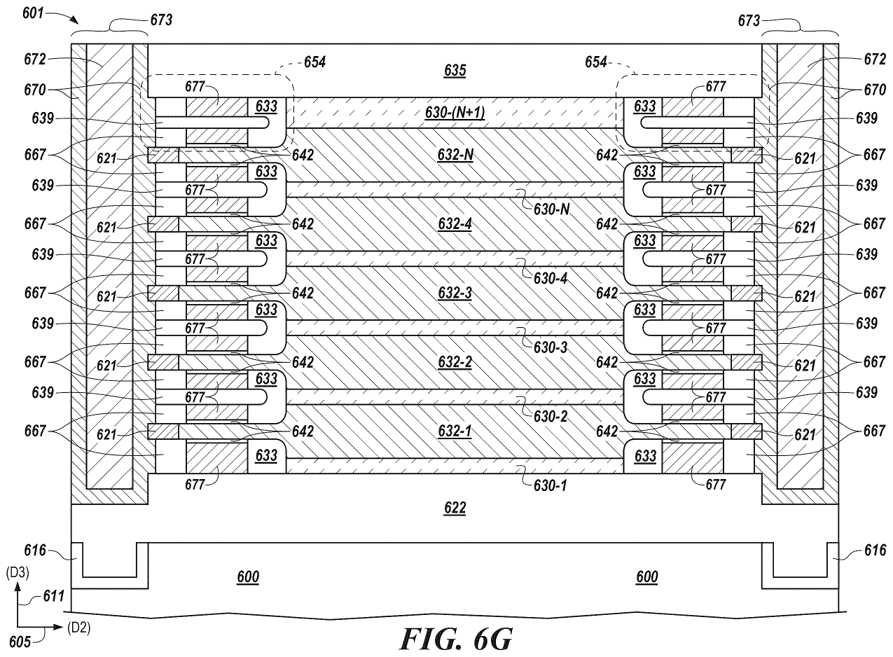

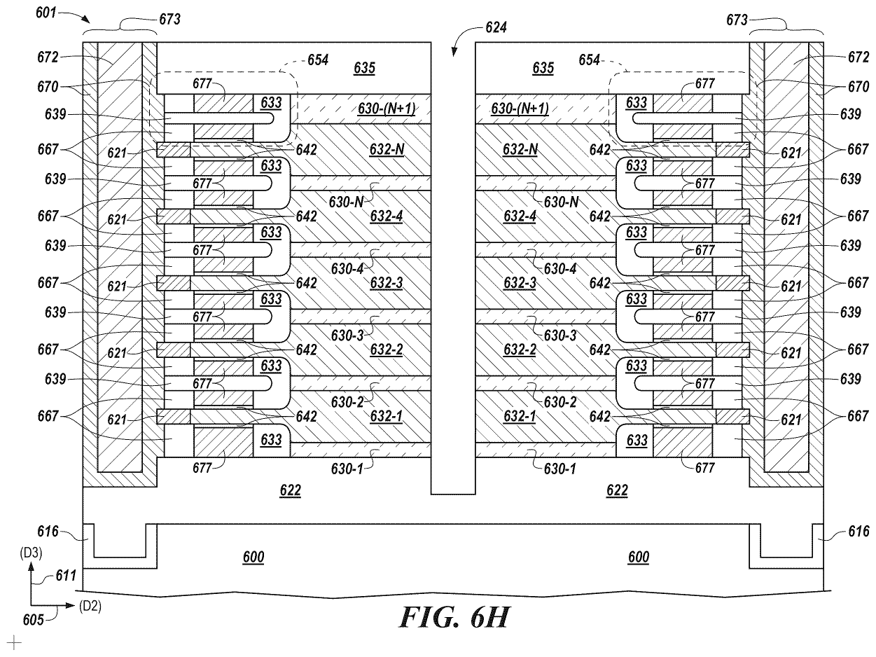

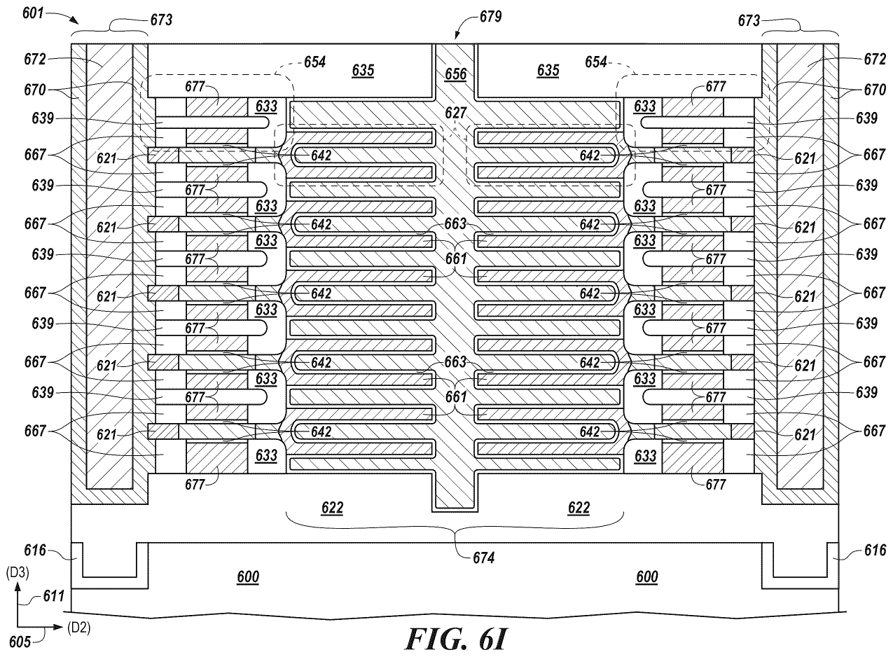

FIG. 6A illustrates an example method, at one stage of a semiconductor fabrication process, for substrate isolation in a 3D memory array, in accordance with a number of embodiments of the present disclosure. FIG. 6A illustrates a side view of a semiconductor structure, at a particular point in time, in a semiconductor fabrication process, according to one or more embodiments. In the example embodiment shown in the example of FIG. 6A, the method comprises using an etching process to form a plurality of first vertical openings 615-1, 615-2 (individually or collectively referred to as first vertical openings 615), having a first horizontal direction (D1) 609 and a second horizontal direction (D2) 605, through the vertical stack to the substrate.

As illustrated in FIG. 6A, the first vertical openings 615 can be formed in a vertical direction 611 through the vertical stack 601 and into the substrate material 600 and extend predominantly in a first horizontal direction 605 to expose first vertical sidewalls in the vertical stack 601 and the substrate material 600. In some embodiments, the first vertical openings 615-1 and 615-2 can be formed at the same time. In other embodiments, the first vertical opening 615-1 can be formed at a different time than the first vertical opening 615-2 is formed. As illustrated in FIG. 6A, a mask material 635 can be formed on the vertical stack 601 such that the portion of the vertical stack that is covered by the mask material 635 is not removed during the etch process that forms the first vertical openings 615.

The method can further include doping a layer of Si or SiGe material to form a layer of doped Si material 631. In some embodiments, the doped Si material 631 can be a doped Si material or doped SiGe material. The dopant can be deposited into the Si material to form the doped Si material 631 through the first vertical openings 615. In some embodiments, the doped Si material 631 can be doped with a boron (B) material, a phosphorous (P) material, and/or a carbon (C) material, among other types of materials.

FIG. 6B illustrates an example method, at another stage of a semiconductor fabrication process, for substrate isolation in a 3D memory array, in accordance with a number of embodiments of the present disclosure. As shown in FIG. 6B, a passivation material 616 can be formed on the sidewalls of the vertical stack 601 and the substrate 600 at a bottom portion of each of the first vertical openings 615. In some embodiments, the passivation material 616 can be epitaxially grown on the sidewalls of the vertical stack 601 and the bottom portion of the first vertical openings 615. In some embodiments, the passivation material 616 can be an oxide material and or a tungsten (W) material.

Further, in some embodiments, the passivation material 616 can be selective to the doped Si material 631. As shown in FIG. 6B, the passivation material 616 can be formed on the sidewalls of the vertical stack 601 such that the passivation material 616 is formed on a portion of the doped Si material 631 but is not formed on a different portion of the doped Si material 631. In some embodiments, the passivation material 616 is not formed on a portion of the doped Si material 631.

FIG. 6C illustrates an example method, at another stage of a semiconductor fabrication process, for substrate isolation in a 3D memory array, in accordance with a number of embodiments of the present disclosure. As shown in FIG. 6C, the method can include removing the doped Si material to form a horizontal opening 618. In some embodiments, the etch process used to remove the doped Si material can be a selective etch process. As shown in FIG. 6C, the passivation material 616 formed on the sidewalls of the vertical stack 601 and formed in the bottom portion of the vertical openings 615 can remain after the horizontal opening 618 is formed.

FIG. 6D illustrates an example method, at another stage of a semiconductor fabrication process, for substrate isolation in a 3D memory array, in accordance with a number of embodiments of the present disclosure. In some embodiments, the method can include depositing a dielectric material 622 in the first vertical openings (e.g., first vertical openings 615 in FIGS. 6A-6C) and the horizontal opening (e.g., horizontal opening 618 in FIG. 6C). As shown in FIG. 6D, dielectric material 622 can be formed over the passivation material 622.

FIG. 6E illustrates an example method, at another stage of a semiconductor fabrication process, for substrate isolation in a 3D memory array, in accordance with a number of embodiments of the present disclosure. As shown in FIG. 6E, the method can include removing a first portion of the dielectric material 622 to reform a portion of the first vertical openings 615 and expose the sidewalls of the vertical stack 601. In some embodiments, the etch used to re-form a portion of the first vertical openings can also remove the passivation material 616 formed on the sidewalls of the vertical stack 601. In some embodiments, the bottom of the portions of the re-formed first vertical openings 615 can extend below a bottom surface of the vertical stack 601 and into the dielectric material 622. Further, in some embodiments, the re-formed portions of the first vertical opening 615 can be formed directly above the portions of the passivation material 616 in the substrate 600.

FIG. 6F illustrates an example method, at another stage of a semiconductor fabrication process, for substrate isolation in a 3D memory array, in accordance with a number of embodiments of the present disclosure. As shown in FIG. 6F, the method can further include forming horizontal access devices 654 in the vertical stack 601. Each of the horizontal access devices 654 can include the first dielectric material 639, the second dielectric material 633, the first conductive material 677, a third dielectric material 667, and an interlayer dielectric material 642. In some embodiments, the first dielectric material 639 can be formed using an oxide material. Further, in some embodiments, the first dielectric material 639 and the second dielectric material 633 can be formed from the same material. In other embodiments, a first material can be used to form the first dielectric material 639 and a second material can be used to form the second dielectric material 633, wherein the first material is a different material than the second material.

FIG. 6G illustrates an example method, at another stage of a semiconductor fabrication process, for substrate isolation in a 3D memory array, in accordance with a number of embodiments of the present disclosure. As shown in FIG. 6G, the method can include forming a vertical sense line 673 in the re-formed portion of each first vertical opening 615. In some embodiments, the vertical sense line 673 can comprise a second conductive material 670 and then depositing a metal material 672 over the second conductive material 670. Further, as shown in FIG. 6G, the second conductive material 670 of the vertical sense line 673 can be in direct physical contact with access devices 654 and source/drain regions 621.

FIG. 6H illustrates an example method, at another stage of a semiconductor fabrication process, for substrate isolation in a 3D memory array, in accordance with a number of embodiments of the present disclosure. As shown in FIG. 6H, the method can include forming a second vertical opening 624 through the vertical stack 601 and into the dielectric material 622. In some embodiments, the second vertical opening 624 can extend below a bottom surface of the vertical stack 601 to a distance that is different than a distance to which the vertical sense lines 673 extend below the bottom surface of the vertical stack 601. In some embodiments, the etches used to form the first vertical openings, the portions of the re-formed vertical openings, the second vertical openings, and the horizontal opening can be wet etches.

FIG. 6I illustrates an example method, at another stage of a semiconductor fabrication process, for substrate isolation in a 3D memory array, in accordance with a number of embodiments of the present disclosure. As shown in FIG. 6I, the method for substrate isolation in a 3D memory array can include forming horizontal storage nodes 627 in the vertical stack 601 and adjacent the second vertical opening 624. The storage node region 674 can include storage nodes 627 (e.g., horizontally oriented capacitor cells) having the first electrodes 661, e.g., bottom electrodes to be coupled to source/drain regions of horizontal access devices 654, and second electrodes 656, e.g., top electrodes to be coupled to a common electrode plane such as a ground plane. The storage nodes 627 are shown formed in a third horizontal opening, extending in second direction (D2) 605, left and right in the plane of the drawing sheet, a third distance from the vertical opening formed in the vertical stack and along an axis of orientation of the horizontal access devices 654 and horizontal storage nodes 674 of the arrays of vertically stacked memory cells of the three-dimensional (3D) memory. In FIG. 6I, a neighboring, horizontal access line is illustrated adjacent the second dielectric material 633, with a portion of the first conductive material 677 located above the Si material 632, and a portion of the first conductive material 677 located below the Si material 632 extending in a direction inward and outward from the plane and orientation of the drawing sheet.

In some embodiments, the vertical top electrode 656 adjacent the horizontally oriented storage nodes 627 can be shared between storage nodes 627 of adjacent arrays to form a shared electrode in the 3D array of vertically stacked memory cells. Further, in some embodiments, the shared electrode for storage nodes 627 to the 3D array of vertically stacked memory cells extends below a bottom surface of the 3D array of vertically stacked memory cells a different depth into the horizontal dielectric material 622 than a bottom surface of the vertical sense line material 673.

In some embodiments, anchors can be formed between different each vertical stack 601. As used herein, the term “anchors” refers to structures between different vertical stacks 601 that brace each vertical stack 601 such that the vertical stacks remain upright during different processing steps being performed on the vertical stack 601. In some embodiments, the processing steps being performed on the vertical stack 601 can include, but are not limited to, deposition processes and etching processes.

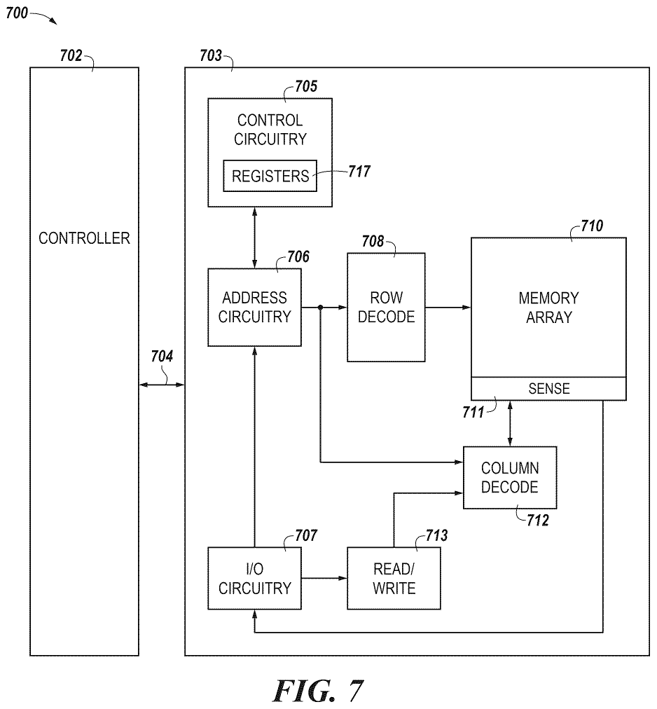

FIG. 7 is a block diagram of an apparatus in the form of a computing system 700 including a memory device 703 in accordance with a number of embodiments of the present disclosure. As used herein, a memory device 703, a memory array 710, and/or a host 702, for example, might also be separately considered an “apparatus. ” According to embodiments, the memory device 703 may comprise at least one memory array 710 with a memory cell formed having a digit line and body contact, according to the embodiments described herein.

In this example, system 700 includes a host 702 coupled to memory device 703 via an interface 704. The computing system 700 can be a personal laptop computer, a desktop computer, a digital camera, a mobile telephone, a memory card reader, or an Internet-of-Things (IoT) enabled device, among various other types of systems. Host 702 can include a number of processing resources (e.g., one or more processors, microprocessors, or some other type of controlling circuitry) capable of accessing memory 703. The system 700 can include separate integrated circuits, or both the host 702 and the memory device 703 can be on the same integrated circuit. For example, the host 702 may be a system controller of a memory system comprising multiple memory devices 703, with the control circuitry (e.g., system controller) 705 providing access to the respective memory devices 703 by another processing resource such as a central processing unit (CPU). In some embodiments, the control circuitry 705 can include registers 717 for storing data.

In the example shown in FIG. 7, the host 702 is responsible for executing an operating system (OS) and/or various applications (e.g., processes) that can be loaded thereto (e.g., from memory device 703 via controller 705). The OS and/or various applications can be loaded from the memory device 703 by providing access commands from the host 702 to the memory device 703 to access the data comprising the OS and/or the various applications. The host 702 can also access data utilized by the OS and/or various applications by providing access commands to the memory device 703 to retrieve said data utilized in the execution of the OS and/or the various applications.

For clarity, the system 700 has been simplified to focus on features with particular relevance to the present disclosure. The memory array 710 can be a DRAM array comprising at least one memory cell having a digit line and body contact formed according to the techniques described herein. For example, the memory array 710 can be an unshielded DL 4F2 array such as a 3D-DRAM memory array. The array 710 can comprise memory cells arranged in rows coupled by word lines (which may be referred to herein as access lines or select lines) and columns coupled by digit lines (which may be referred to herein as sense lines or data lines). Although a single array 710 is shown in FIG. 7, embodiments are not so limited. For instance, memory device 703 may include a number of arrays 710 (e.g., a number of banks of DRAM cells).

The memory device 703 includes address circuitry 706 to latch address signals provided over an interface 704. The interface 704 can include, for example, a physical interface employing a suitable protocol (e.g., a data bus, an address bus, and a command bus, or a combined data/address/command bus). Such protocol may be custom or proprietary, or the interface 704 may employ a standardized protocol, such as Peripheral Component Interconnect Express (PCIe), Gen-Z, CCIX, or the like. Address signals are received and decoded by a row decoder 708 and a column decoder 712 to access the memory array 710. Data can be read from memory array 710 by sensing voltage and/or current changes on the sense lines using sensing circuitry 711. The sensing circuitry 711 can comprise, for example, sense amplifiers that can read and latch a page (e.g., row) of data from the memory array 710. The I/O circuitry 707 can be used for bi-directional data communication with the host 702 over the interface 704. The read/write circuitry 713 is used to write data to the memory array 710 or read data from the memory array 710. As an example, the circuitry 713 can comprise various drivers, latch circuitry, etc.

Control circuitry 705 decodes signals provided by the host 702. The signals can be commands provided by the host 702. These signals can include chip enable signals, write enable signals, and address latch signals that are used to control operations performed on the memory array 710, including data read operations, data write operations, and data erase operations. In various embodiments, the control circuitry 705 is responsible for executing instructions from the host 702. The control circuitry 705 can comprise a state machine, a sequencer, and/or some other type of control circuitry, which may be implemented in the form of hardware, firmware, or software, or any combination of the three. In some examples, the host 702 can be a controller external to the memory device 703. For example, the host 702 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular. ” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for forming three dimensional (3D) arrays of vertically stacked memory cells, having horizontally oriented access devices and storage nodes, comprising:
forming a vertical stack comprising alternating layers of a first material and a second material on a substrate;
forming first vertical openings through the vertical stack and into the substrate to form sidewalls of the vertical stack;
forming a doped silicon (Si) material on a substrate;
forming a passivation material on the sidewalls of the vertical stack and a bottom portion of each first vertical opening;
removing the doped silicon material to form a horizontal opening;
depositing a dielectric material in the first vertical openings and the horizontal opening;
removing a first portion of the dielectric material to reform a portion of the first vertical openings and expose the sidewalls of the vertical stack;
forming horizontal access devices in the vertical stack;
forming a vertical sense line in the reformed portion of each of the first vertical openings;
forming a second vertical opening through the vertical stack and into the dielectric material;
forming horizontal storage nodes in the vertical stack and adjacent the second vertical opening.

2. The method of claim 1, further comprising epitaxially growing the doped Si material on the substrate.

3. The method of claim 1, wherein the doped Si material is a doped silicon germanium (SiGe) material.

4. The method of claim 1, further comprising epitaxially growing the passivation material on the sidewalls of the vertical stack and the bottom portion of each first vertical opening.

5. The method of claim 1, wherein the passivation material is an oxide material.

6. The method of claim 1, wherein the passivation material is a tungsten (W) material.

7. The method of claim 1, wherein the first material is a silicon germanium (SiGe) material.

8. The method of claim 1, wherein the second material is a Si material.

9. A method for forming three dimensional (3D) arrays of vertically stacked memory cells, having horizontally oriented access devices and storage nodes, comprising:
depositing alternating layers of silicon germanium (SiGe) material and Si material to form a vertical stack on a substrate;
depositing a mask material over the vertical stack;
performing a first etch to form first vertical openings through the vertical stack and into the substrate to from sidewalls of the vertical stack;
doping a layer of silicon (Si) material on the substrate to form doped Si material on the substrate;
epitaxially growing passivation material on the sidewalls of the vertical stack and a bottom portion of the first vertical openings;
performing a second etch to remove the doped Si material on the substrate to create a horizontal opening;
depositing a dielectric material in the first vertical openings and the horizontal opening;
performing a third etch to remove portions of the dielectric material to reform portions of the first vertical openings and expose the sidewalls of the vertical stack;
forming horizontal access devices in the vertical stack;
depositing a sense line in the portions of the first vertical openings;
performing a fourth etch to form second vertical openings through the vertical stack and into the dielectric material; and
forming horizontal storage nodes in the vertical stack adjacent the second vertical openings.

10. The method of claim 9, further comprising depositing a fill material to fill the third vertical openings.

11. The method of claim 9, further comprising forming anchors between parallel vertical stacks.

12. The method of claim 9, wherein the first etch, the second etch, the third etch, and the fourth etch are each wet etches.

13. The method of claim 9, wherein the third etch removes the passivation material from the sidewalls of the vertical stack.

14. The method of claim 9, further comprising depositing the dielectric material over the substrate and the passivation material formed on the bottom portion of the first vertical openings.

15. The method of claim 9, further comprising doping the doped Si material with a boron (B) material.

16. The method of claim 9, further comprising doping the doped Si material with a phosphorous (P) material.

17. The method of claim 9, further comprising doping the doped Si material with a carbon (C) material.

18. A memory device comprising:
a substrate;
a horizontal dielectric material formed on the substrate;
a three dimensional (3D) array of vertically stacked memory cells formed on the dielectric material, the vertically stacked memory cells having horizontally oriented access devices and horizontally oriented storage nodes; and
vertical sense line material formed adjacent to, and in contact with, the horizontally oriented access devices, wherein the vertical sense line material is formed on the horizontal dielectric material such that a bottom portion of the vertical sense line material extends below a bottom surface of the 3D array of vertically stacked memory cells and into the horizontal dielectric material.

19. The memory device of claim 18, wherein a vertical top electrode adjacent the horizontally oriented storage nodes is shared between storage nodes of adjacent arrays to form a shared electrode in the 3D array of vertically stacked memory cells.

20. The memory device of claim 19, wherein the shared electrode for storage nodes to the 3D array of vertically stacked memory cells extends below a bottom surface of the 3D array of vertically stacked memory cells a different depth into the horizontal dielectric material than a bottom surface of the vertical sense line material.
